(19) United States
(12) Patent Application Publication
(10) Pub. No.: US 2009/0220705 A1
(43) Pub. Date: Sep. 3, 2009

(54) METHOD FOR MANUFACTURING ORGANIC EL DISPLAY DEVICE

(76) Inventors: Yukitami MIZUNO, Tokyo (JP); Shintaro Enomoto, Yokohama-shi (JP); Miho Yoda, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/388,838

(22) Filed: Feb. 19, 2009

(30) Foreign Application Priority Data
Mar. 3, 2008 (JP) 2008-052449

(51) Int. Cl. B05D 5/12

(52) U.S. Cl. 427/555; 427/532; 427/557

(57) ABSTRACT

A method for manufacturing an organic EL display device is provided, which includes forming a first emission layer via a hole injection transport layer over a substrate having first, second and third anode electrodes formed thereon, irradiating the second and third anode electrodes with light, to remove the first emission layer selectively to expose the hole injection transport layer on the second and third anode electrodes, forming a second emission layer, on the first emission layer and on the exposed hole injection transport layer, irradiating the third anode electrode with light to remove the second emission layer selectively, to expose the hole injection transport layer on the third anode electrode, forming a third emission layer, on the second emission layer and on the exposed hole injection transport layer, and forming a cathode electrode over the first, second and third anode electrodes via at least one of the emission layers.

### CROSS-REFERENCE TO RELATED APPLICATIONS

This application is based upon and claims the benefit of priority from prior Japanese Patent Application No. 2008-052449, filed Mar. 3, 2008, the entire contents of which are incorporated herein by reference.

### BACKGROUND OF THE INVENTION

1. Field of the Invention

The present invention relates to a display device including an emission layer showing an electroluminescence (EL) phenomenon.

2. Description of the Related Art

A light source utilizing an electroluminescence (EL) phenomenon is studied and developed for the purpose of a wide range of applications to backlights in illuminating devices and displays and to emission devices such as luminescent pixels in displays.

For color displaying in displays, pixels should emit red, green and blue lights respectively. For realizing such color lights by the respective pixels, a diode having an emission layer that emits a red, green or blue light should be arranged in each pixel. In patterning the emission layer showing each luminescence color, the following two methods are conventionally used.

One is a method of forming a film of an emission layer material by vapor deposition with a mask for covering portions not required to form a layer and is described in, for example, Japanese Patent No. 3401356. In this case, there is an advantage that a luminescent material is formed uniformly into a film, and during the deposition process, the luminescent material is refined by sublimation. However, when a large display is manufactured, a large mask is necessary and the weight of the mask is increased. As the mask is enlarged, slight deformation of the mask can cause deviation from the right position in making a film.

Another method is a method in which liquid droplets having a luminescent material dissolved therein are applied by ink jetting or the like onto desired positions to form a film thereon, and this method is described in, for example, Japanese Patent No. 3036436. This method can solve the disadvantage of using a mask, but when a solution is applied, a uniform film is hardly formed. In addition, complete removal of impurities such as solvent is difficult, so there is a problem that a factor causing short lifetime in the emission layer cannot be eliminated.

### BRIEF SUMMARY OF THE INVENTION

A method for manufacturing an organic EL display device according to one aspect of the present invention comprises:

forming first, second and third anode electrodes on a surface of a substrate;

forming a hole injection transport layer on the substrate on which the first, second and third anode electrodes have been formed;

forming a first emission layer containing a first luminescent material, on the whole surface of the hole injection transport layer;

irradiating the second and third anode electrodes with light, to remove the first emission layer selectively to expose the hole injection transport layer on the second and third anode electrodes;

forming a second emission layer containing a second luminescent material, on the first emission layer and on the exposed hole injection transport layer;

irradiating the third anode electrode with light to remove the second emission layer selectively, to expose the hole injection transport layer on the third anode electrode;

forming a third emission layer containing a third luminescent material, on the second emission layer and on the exposed hole injection transport layer; and

forming a cathode electrode over the first, second and third anode electrodes via at least one of the first, second and third emission layers.

A method for manufacturing an organic EL display device according to another aspect of the present invention comprises:

forming first, second and third anode electrodes and a hole injection transport layer successively on each of two substrates, to prepare a first substrate having a hole injection transport layer and a second substrate having a hole injection transport layer;

forming a first emission layer containing a first luminescent material, on the whole surface of the hole injection transport layer in the first substrate having a hole injection transport layer;

arranging the first emission layer in the first substrate having a hole injection transport layer opposite to the hole injection transport layer in the second substrate having a hole injection transport layer with a gap between the two layers;

irradiating the second and third anode electrodes in the first substrate having a hole injection transport layer with light, to remove the first luminescent material selectively, thereby exposing the hole injection transport layer on the second and third anode electrodes in the first substrate having a hole injection transport layer and simultaneously depositing the removed first luminescent material on the hole injection transport layer on the first and second anode electrodes in the second substrate having a hole injection transport layer, thereby selectively forming a first emission layer on the second substrate.

A method for manufacturing an organic EL display device according to another aspect of the present invention comprises:

forming a hole injection transport layer on a transparent substrate having first, second and third anode electrodes formed thereon;

forming a first emission layer containing a first luminescent material, on the hole injection transport layer;

irradiating the second and third anode electrodes with light applied at the back side of the transparent substrate, to remove the first emission layer selectively to expose the hole injection transport layer on the second and third anode electrodes;

forming a second emission layer containing a second luminescent material, on the first emission layer and on the exposed hole injection transport layer;

irradiating the third anode electrode with light to remove the second emission layer selectively, to expose the hole injection transport layer on the third anode electrode;

forming a third emission layer containing a third luminescent material, on the second emission layer and on the exposed hole injection transport layer; and

forming a cathode electrode over the first, second and third anode electrodes via at least one of the first, second and third emission layers.

### BRIEF DESCRIPTION OF THE SEVERAL VIEWS OF THE DRAWING

FIG. 1 is a sectional view of a light-emitting device according to one embodiment;

FIG. 2 is a sectional view showing a process for manufacturing a light-emitting device according to one embodiment;

FIG. 3 is a sectional view showing a process following FIG. 2;

FIG. 4 is a sectional view showing a process following FIG. 3;

FIG. 5 is a sectional view showing a process following FIG. 4;

FIG. 6 is a sectional view showing a process following FIG. 5;

FIG. 7 is a sectional view showing a process following FIG. 6;

FIG. 8 is a sectional view showing a process following FIG. 7;

FIG. 9 is a sectional view showing a process following FIG. 8;

FIG. 10 is a sectional view showing a process for manufacturing a light-emitting device according to another embodiment; and

FIG. 11 is a sectional view showing a process following FIG. 10.

### DETAILED DESCRIPTION OF THE INVENTION

Hereinafter, embodiments will be described with reference to the drawings.

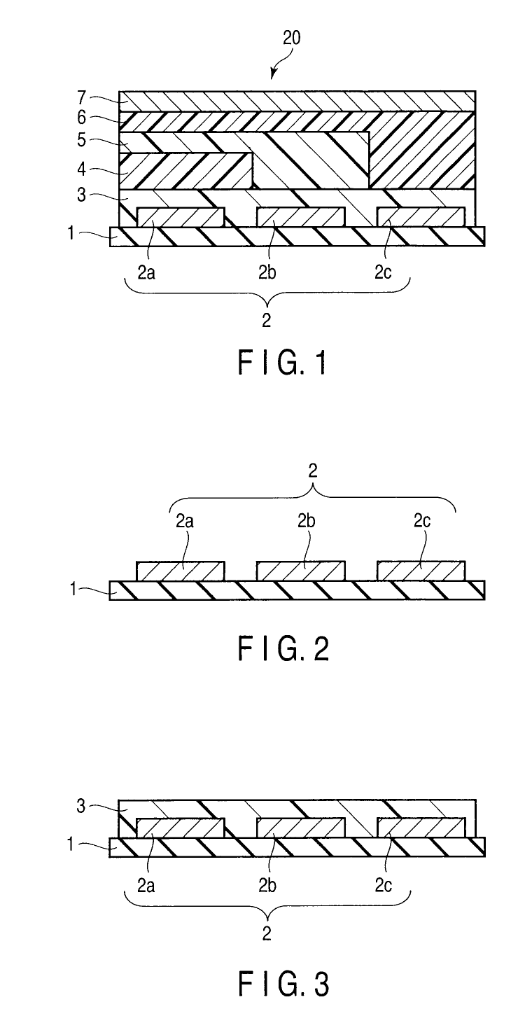

In an organic EL element 20 shown in FIG. 1, anode electrodes 2 and a hole injection transport layer 3 are disposed successively on a substrate 1. The anode electrodes 2 are patterned so as to correspond to pixels (RGB) and are composed of a first anode electrode 2a, a second anode electrode 2b and a third anode electrode 2c. The surface of the hole injection transport layer 3 is divided into first, second and third regions that correspond to the first, second and third anode electrodes 2a, 2b and 2c, respectively.

A first emission layer 4 is formed in the first region of the hole injection transport layer 3 corresponding to the first anode electrode 2a. A second emission layer 5 is formed on the second region of the hole injection transport layer 3 and on the first emission layer 4; a third emission layer 6 is formed on the third region of the hole injection transport layer 3 and on the second emission layer 5; and a cathode electrode 7 is formed on the third emission layer 6.

A method for manufacturing the display device according to the present embodiment will be described with reference to FIGS. 2 to 9.

As shown in FIG. 2, anode electrodes 2a, 2b and 2c are first formed on the substrate 1. The substrate 1 can be composed of an arbitrary material having sufficient strength in a step of forming anode electrodes and an organic EL device.

When the anode electrodes 2 are formed by sputtering or vapor deposition, the substrate 1 is desirably a material not deformed even under the condition of higher than 200° C. Examples of such material include glass, quartz, and silicon.

A transparent substrate made of glass, quartz or the like is advantageous in that luminescence can be drawn through the substrate. On the other hand, an opaque substrate made of silicon or the like is advantageous in that the substrate can be strengthened with various additives.

When the anode electrodes 2 are formed at ordinary temperatures for example by transfer or printing, a plastic substrate or the like can be used as the substrate 1. Examples of substrate materials include polyethylene terephthalate, polyether imide, polyether ether ketone, polyether sulfone, polyethylene naphthalate, polyimide, polyphenylene sulfide, polyethylene, and polycarbonate.

The anode electrodes 2 are made of a material that can be not only electrified but also heated by irradiation with light. To increase the efficiency of conversion of light to heat, the light transmittance of the material is desirably lower. Specifically, the transmittance is preferably 10% or less. The transmittance can be measured for example with a visible-ultraviolet spectrophotometer. To increase the efficiency of conversion of light to heat, the light absorption of the material is preferably higher. Specifically, the absorption is preferably 50% or more. The absorption can be determined for example by measuring a change in increase of the temperature of the anode relative to the quantity of irradiated light.

When a metal for example is used in the anode electrode, silver, aluminum, molybdenum or the like can be formed into a film of 100 nm or more as the anode electrode 2. When the anode electrode is less than 100 nm in thickness, the light transmittance may be increased. To achieve efficient conversion of light to heat, a black and highly light-absorbing metal such as molybdenum is preferably used to form the anode electrode. A black electrode such as a carbon electrode may also be used as the anode electrode 2.

The anode electrode is usually 5 to 5000 μm in length and 5 to 5000 μm in width. The distance between the neighboring anode electrodes is usually about 10 to 100 μm and can be appropriately selected depending on the thermal conductivity of the substrate, etc.

As shown in FIG. 3, the substrate 1 on which the anode electrodes 2a, 2b and 2c have been formed is provided thereon with a hole injection transport layer 3. The hole injection transport layer 3 is a layer for injecting or transporting a positive hole into an emission layer. As described later, the predetermined anode electrode is heated in a later step during which the hole injection transport layer 3 is also heated to a certain degree. Heating of the anode electrode is conducted for sublimating or evaporating a luminescence material, so it should be avoided as much as possible for such heating to exert influence on the hole injection transport layer 3.

Accordingly, the temperature at which the hole injection transport layer 3 is sublimated or evaporated is required to be higher than the temperature necessary for sublimation or evaporation of the luminescence material. The difference between the temperatures is preferably 10° C. or more from the viewpoint of control of temperature.

As the material of the hole injection transport layer 3, it is possible to use a composite material between polyethylene dioxythiophene and polystyrenesulfonic acid or a polymer material such as polypyrrole, polythiophene or polyvinyl carbazole. Film formation can be carried out by a method such as vapor deposition, ink jetting or spin coating, to form a film wholly or partially on the substrate.

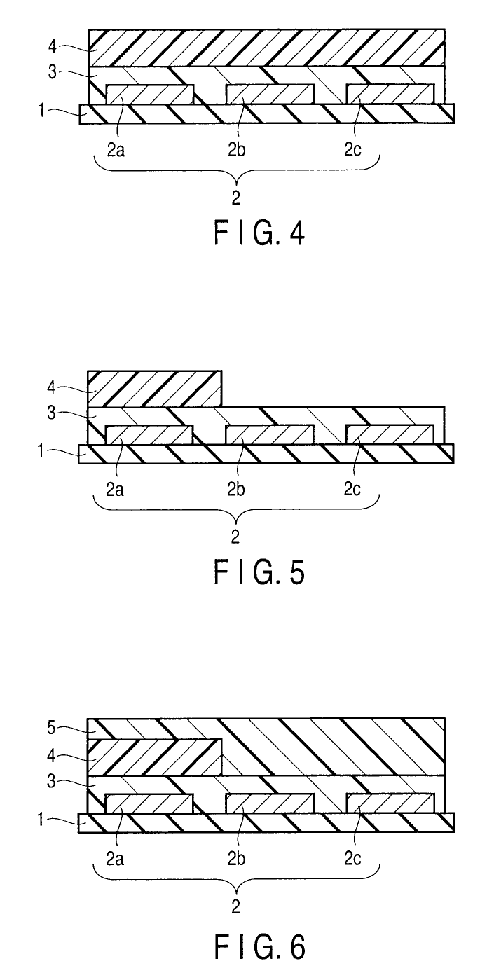

On the whole surface of the hole injection transport layer 3, a first emission layer 4 is formed by using a first luminescent material, as shown in FIG. 4. The first luminescent material 1 is a red luminescent material, and examples include butyl-6-(1,1,7,7-tetramethyljulolidyl-9-enyl)-4H-pyran (DCJTB), TMS-SiPc, rubrene, octaethyl platinum porphyrin, benzothienyl pyridine-acetyl acetone-iridium complex, terylene, perinone, and Nile Red. The first emission layer can be formed on the whole surface of the substrate by vapor deposition, ink jetting, or spin coating. For preventing the first emission layer from merging into a second emission layer formed thereon, the first emission layer 4 is formed preferably by vapor deposition on the whole surface.

The thickness of the first emission layer 4 can be appropriately determined depending on the mobility of a carrier, light transmittance, emission wavelength, and color purity. The thickness is usually about 0.01 to 0.2 μm.

The first, second and third anode electrodes 2a, 2b and 2c correspond to first, second and third pixels, respectively. Accordingly, the first emission layer 4 is disposed selectively on the first anode electrode 2a. In the method according to the embodiment, the first emission layer 4 disposed over the whole surface of the substrate 1 on which the first, second and third anode electrodes 2a, 2b and 2c have been formed is selectively removed, thereby disposing the first emission layer 4 selectively on the hole injection transport layer 3 of the first anode electrode 2a.

Selective removal of the first emission layer 4 can be achieved by sublimation or evaporation of the luminescent material in the predetermined region. Specifically, the second anode electrode 2b and the third anode electrode 2c are selectively heated, thereby heating the first emission layer 4 selectively via the hole injection transport layer 3 disposed on these electrodes. As a result, the first luminescent material in the heated region is removed by sublimation or evaporation, so that as shown in FIG. 5, the hole injection transport layer 3 on the second anode electrode 2b and on the third anode electrode 2c is exposed.

Selective heating of the second anode electrode 2b and the third anode electrode 2c may be conducted by direct heating, but preferably by light irradiation. By heating with light irradiation, selective heating can be performed on the predetermined position. A light source used in heating includes an incandescent lamp, a laser beam etc., among which a laser beam is desirably used in consideration of selectivity and efficiency. When the anode electrodes 2b and 2c are formed from molybdenum, a laser beam having a wavelength in the range of 380 to 10600 nm is preferably used.

When the wavelength of a laser beam is 380 nm or more, the deterioration in the substrate and luminescent material by irradiated light can be prevented. When light of a wavelength longer than 700 nm is used, the objective anode electrodes can be efficiently heated. Light of a wavelength longer than 10600 nm is not desirable in that a light such as laser light is obtained. Irradiated light is not required to have a single wavelength, and may have wavelengths distributed in a broad range as in sunray or light from a light source such as a halogen lamp. Light of wavelengths outside of the absorption wavelength of the luminescent material is preferably used because the deterioration of the luminescent material can be prevented.

When the anode electrode is irradiated with a laser beam, the whole of the anode electrode is heated through conduction of heat in the electrode. Accordingly, it is not necessary to irradiate the whole surface of the objective anode electrode with a laser beam, and a partial region of the surface may be irradiated to achieve the intended effect.

The beam diameter of an irradiated laser is desirably smaller than the anode electrode. When the beam diameter is too large, a neighboring pixel may also be heated. When the beam diameter is smaller than the anode electrode, a part of the anode electrode may be heated so that the whole of the anode electrode can be heated through conduction of heat. By prescribing the beam diameter in a predetermined range, only the luminescent material on the predetermined anode electrode can be heated.

When the substrate 1 is composed of a transparent substrate such as glass or quartz, a laser beam may be applied through the substrate onto the second anode electrode 2b and the third anode electrode 2c. In this case, the deterioration in the luminescent material by light can be advantageously prevented.

As already described, the hole injection transport layer 3 is composed of a material that is not sublimated or evaporated by heating. Accordingly, the hole injection transport layer 3 does not undergo any influence even upon subjection to irradiation with a laser beam for allowing the first emission layer 4 to be selectively left. Accordingly, a laser beam may be applied at the side of the front face of the substrate 1. In this case, there is an advantage that it is not necessary to consider the influence of the transmittance and light absorption of the substrate.

The sublimation or evaporation of the luminescent material by heating the predetermined anode electrode can be performed at ordinary pressures in air or a nitrogen atmosphere. The same conditions as in film formation by vapor deposition are desirable for efficient sublimation or evaporation of the luminescent material. The degree of vacuum in sublimation or evaporation is desirably lower, more desirably not higher than 10⁻⁶ torr.

On the patterned first emission layer 4 and on the whole surface of the exposed hole injection transport layer 3, a second emission layer 5 is formed from a second luminescent material, as shown in FIG. 6. The second luminescent material is a green luminescent material, and examples thereof include an aluminoquinoline complex, a bis(benzoquinolinato)beryllium complex, quinacridone, coumarin, anthracene, and diphenyltetracene.

The second emission layer, similar to the first emission layer, can also be formed by vapor deposition, ink jetting or spin coating, over the whole surface of the substrate on which the first emission layer 4 has been disposed. For preventing the second emission layer from merging into a third emission layer to be formed later, the second emission layer is formed preferably by vapor deposition.

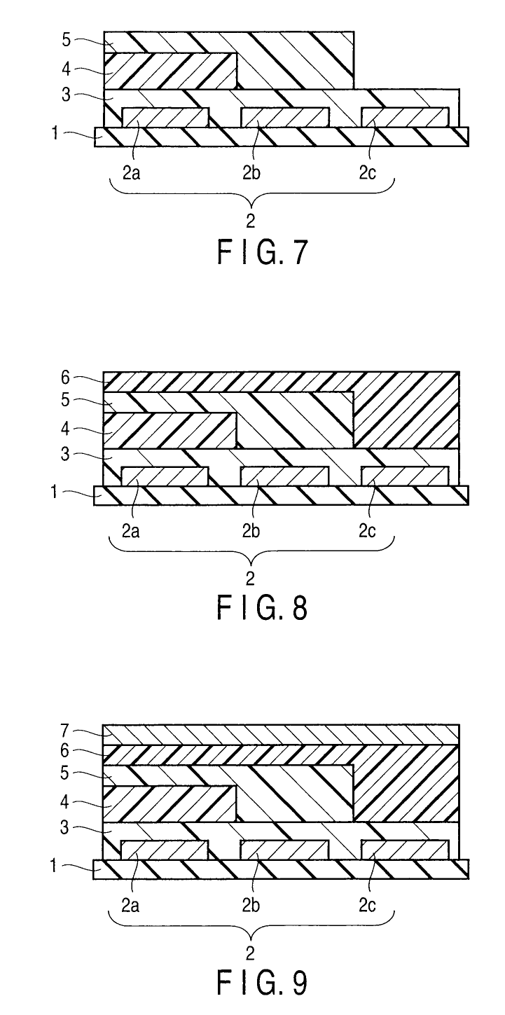

The second emission layer 5 is selectively removed, thereby exposing the surface of the hole injection transport layer 3 on the third anode electrode 2c as shown in FIG. 7. Selective removal of the second emission layer is carried out by selectively heating the third anode electrode 2c thereby selectively sublimating or evaporating the second luminescent material over this region.

When the third anode electrode 2c is formed from molybdenum, a laser beam having a wavelength in the range of 380 to 10600 nm can be preferably used as described above.

However, the beam diameter of a laser to be applied herein is desirably smaller than the anode electrode 2c, unlike the previous description. When the beam diameter is too large, the luminescent material over the anode electrodes 2a and 2b may be sublimated or evaporated. When the beam diameter is smaller than the anode electrode 2c, a part of the anode electrode may be heated so that the whole of the anode electrode can be heated through conduction of heat.

The conditions except for the beam diameter of a laser can be the same as described above, and the substrate 1 may be irradiated either at the front or back side thereof with a laser beam.

The second emission layer may not necessarily be left on the first emission layer. When the first luminescent material used has a sublimation point and an evaporation temperature higher than those of the second luminescent material, the first emission layer can be left while the second emission layer thereon can be removed by irradiating the first anode electrode 2a with a laser beam. In this case, the sublimation point and evaporation temperature of the first luminescent material are higher preferably by at least 50° C. than those of the second luminescent material.

On the patterned second emission layer 5 and on the whole surface of the exposed hole injection transport layer 3, a third emission layer 6 is formed using a third luminescent material, as shown in FIG. 8. The third luminescent material is a blue luminescent material, and examples thereof include 2-tert-butyl-9,10-di(naphthalen-2-yl), perylene, tetraphenylanthracene, tetraphenylbutadiene, and 9,10-bis(phenylethnynyl)anthracene.

The third emission layer, similar to the first and second emission layers, can also be formed by vapor deposition, ink jetting or spin coating, over the whole surface of the substrate over which the first emission layer 4 and the second emission layer 5 have been disposed. For forming the third emission layer 6 over the whole surface of the large substrate, the layer is formed preferably by vapor deposition.

As is the case with the second emission layer that is not necessarily required to remain on the first emission layer, the third emission layer is not necessarily required to remain on the second emission layer (and the first emission layer). When the second luminescent material (and the first luminescent material) used has a sublimation point and an evaporation temperature higher than those of the third luminescent material, the second emission layer (and the first emission layer) can be left while the third emission layer thereon can be removed by irradiating the second anode electrode 2a (and the first anode electrode 2b) with a laser beam. In this case, the sublimation point and evaporation temperature of the second luminescent material (and the first luminescent material) are higher preferably by at least 50° C. than those of the third luminescent material.

As shown in FIG. 8, the first, second and third emission layers 4, 5 and 6 are disposed and contacted directly with the surface of the hole injection transport layer 3. The first, second and third emission layers 4, 5 and 6 correspond to the first, second and third anode electrodes 2a, 2b and 2c just below the hole injection transport layer 3.

As shown in FIG. 9, a cathode electrode 7 is formed on the third emission layer 6. Although not shown in the figure, an electron injection transport layer for injecting and transporting an electron may be disposed between the third emission layer and the cathode layer 7. These layers are formed desirably by vapor deposition. The material of the electron injection transport layer includes, for example, tris(8-quinolinol)aluminum, benzotriazole zinc, and 3,4,9,10-perylenetetracarboxyl-bis-benzimidazole.

The material of the cathode electrode 7 is preferably a material with a low work function, more preferably a material with a work function of 3.4 eV or less, in order to inject an electron into the electron transport layer, the electron injection layer and the third emission layer. The material that can be used includes, for example, Li, Na, K, Rb, Cs, Mg, Ca, Sr, and Ba, as well as Al, Ag, Ga, V, Ti, Bi, Sn, Cr, Sb, Cu, Co and Au.

According to the method of the embodiment, the R pixel, G pixel and B pixel can be formed, thus forming a uniform emission layer to produce an organic EL element capable of full-color display, as described above. In addition, the emission layer can be patterned without using a mask, so the deviation from the right position in patterning, resulting from the deformation of a mask, does not occur.

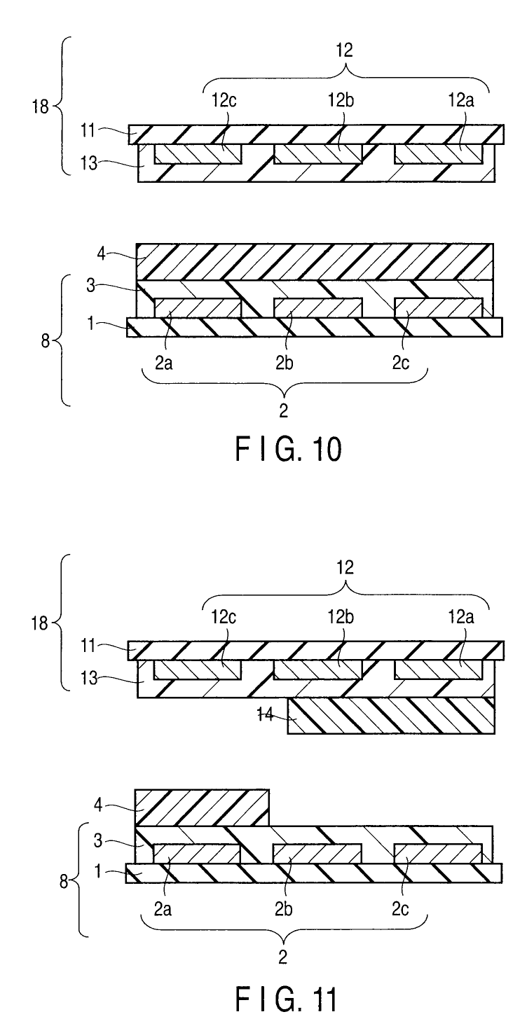

The manufacturing method according to another embodiment will be described with reference to FIGS. 10 and 11.

Two substrates are prepared, and according to the process described with reference to FIGS. 2 and 3, anode electrodes and a hole injection transport layer are formed on the substrates respectively, whereby two substrates each having the hole injection transport layer are prepared. As shown in FIG. 10, the first substrate 8 having a hole injection transport layer has a hole injection transport layer 3 formed on the substrate 1 on which the first, second and third anode electrodes 2a, 2b and 2c have been formed, and the second substrate 18 having a hole injection transport layer has a hole injection transport layer 13 formed on the substrate 11 on which the first, second and third anode electrodes 12a, 12b and 12c have been formed. The two substrates have the same constitution except that in the first substrate 8 having a hole injection transport layer, a first luminescent material is used to form a first emission layer 4 on the hole injection transport layer 3 by the method described above.

The second substrate 18 having a hole injection transport layer is arranged over the first substrate 8 having a hole injection transport layer on which the first emission layer 4 has been formed, such that the hole injection transport layer 13 is opposite to the substrate 8. The second anode electrode 2b and the third anode electrode 2c are irradiated with light applied at the back side of the first substrate 8 having a hole injection transport layer, to remove the first luminescent material of the first emission layer 4 selectively by sublimation or evaporation.

In the first substrate 8 having a hole injection transport layer, the hole injection transport layer 3 on the second anode electrode 2b and on the third anode electrode 2c is exposed as shown in FIG. 11. The removed first luminescent material is formed selectively into a film on the hole injection transport layer 13 of the oppositely arranged second substrate 18 having a hole injection transport layer. As shown in the figure, the second substrate 18 having a hole injection transport layer has a first emission layer 14 formed thereon except for the surface of the hole injection transport layer 13 on the third anode electrode 12c.

A substrate having a hole injection transport layer and an emission layer formed thereon is arranged opposite to a substrate, and by sublimation of the emission layer by heating, its sublimated material is re-deposited onto the opposite substrate, thus advantageously preventing the luminescent material from being lost by sublimation. In addition, the step of sublimation and the step of vapor deposition are simultaneously conducted, thereby reducing the time of patterning of the emission layer and formation of the emission layer.

Hereinafter, concrete examples of the present invention will be described.

### EXAMPLE 1

As the substrate 1, a glass substrate of 0.7 mm in thickness was prepared, and an anode electrode of 500 μm in length and width and 100 nm in thickness and composed of molybdenum was patterned thereon as shown in FIG. 2. The distance between neighboring anode electrodes is about 100 μm. The anode electrodes were 3 types of electrodes for red pixel, green pixel and blue pixel, corresponding to first, second and third anode electrodes 2a, 2b and 2c, respectively.

As the starting material of a hole injection transport layer, an aqueous solution of polyethylene dioxythiophene and polystyrenesulfonic acid (manufactured by Aldrich) was prepared and applied onto the whole surface by spin coating at a rate of 3000 rpm. Thereafter, the substrate was heated at 200° C. for 5 minutes to evaporate water, to form a hole injection transport layer 3 thereon as shown in FIG. 3.

This substrate was placed in a deposition chamber at 10⁻⁶ torr, and rubrene as a first luminescent material was formed as a film on the whole surface, to form a first emission layer 4 as shown in FIG. 4. The thickness of the first emission layer 4 was 40 nm. At this degree of vacuum, the second anode electrode 2b for green pixel and the third anode electrode 2c for blue pixel were irradiated with a laser at 800 nm applied at the side of the substrate. Rubrene as the first luminescent material was thereby selectively sublimated to expose the hole injection transport layer 3 on the second anode electrode 2b and on the third anode electrode 2c as shown in FIG. 5.

While the degree of vacuum in the deposition chamber was maintained, an aluminoquinoline complex as a second luminescent material was formed as a film on the whole surface, to form a second emission layer 5 as shown in FIG. 6. The thickness of the second emission layer 5 was 40 nm. The third anode electrode 2c for blue pixel was irradiated with a laser at 800 nm applied at the side of the substrate. The aluminoquinoline complex as the second luminescent material was thereby selectively sublimated to expose the hole injection transport layer 3 on the third anode electrode 2c as shown in FIG. 7.

As the third luminescent material, diphenyl anthracene was formed as a film on the whole surface to form a third emission layer 6 as shown in FIG. 8. The thickness of the third emission layer 6 was 40 nm.

Finally, magnesium and silver were deposited over the whole surface of the substrate to form a cathode electrode 7 as shown in FIG. 9, thereby producing an organic EL element. By electrifying the first, second and third anode electrodes 2a, 2b and 2c, red, green and blue emissions were observed.

The resulting emission can produce a red, green or blue color alone, so it is estimated that a uniform emission layer was formed in this example.

### COMPARATIVE EXAMPLE

An organic EL element was manufactured by a conventional method using ink jetting. Specifically, anode electrodes and a hole injection transport layer were formed on a glass substrate in the same manner as in Example 1.

On the hole injection transport layer, first to third emission layers were formed by using a luminescent material consisting of a polyfluorene copolymer with a red color or a luminescent material with a green or blue color. Each luminescent material was dissolved to a concentration of about 0.1 wt % in an organic solvent such as xylene to prepare a solution. The resulting solution was applied by ink jetting onto the anode 2. However, it was found that when an emission layer was formed by this method, its thickness was different by 10 nm or more between the center of the anode electrode and the edge of the anode electrode. This was revealed by observation of a section of the layer under a scanning tunneling microscope.

The emission intensity of the resulting organic EL element was varied due to a difference in the thickness of the layer between the center and edge of the emission pixel. Accordingly, it was confirmed that a uniform emission layer cannot be obtained.

### EXAMPLE 2

Anode electrodes and a hole injection transport layer were formed on each of two glass substrates in the same manner as in Example 1, to prepare two substrates each having a hole injection transport layer.

One substrate 8 having a hole injection transport layer had a first emission layer 4 formed thereon in the same manner as in Example 1, then arranged opposite to the hole injection transport layer 13 in the other substrate 18 having a hole injection transport layer, as shown in FIG. 10, and placed in a deposition chamber. The pressure in the chamber was 10⁻⁶ torr.

The second and third anode electrodes 2b and 2c in the first substrate 8 having a hole injection transport layer were irradiated with a laser at 800 nm applied at the back side of the substrate 1. As a result, the hole injection transport layer 3 on the second anode electrode 2b and on the third anode electrode 2c was exposed in the first substrate 8 having a hole injection transport layer, while in the second substrate 18 having a hole injection transport layer, a first emission layer 14 was formed on the hole injection transport layer 13 on the second anode electrode 12a and on the second anode electrode 12b, as shown in FIG. 11.

In the first substrate 8 having a hole injection transport layer, a second emission layer and a third emission layer were successively formed in the same manner as Example 1, and a cathode electrode was arranged thereon to give an organic EL element. In the second substrate 18 having a hole injection transport layer, on the other hand, the first emission layer was removed except for the layer on the anode electrode 2a, and then a second emission layer and a third emission layer were successively formed in the same manner as in Example 1. Finally, a cathode electrode was arranged thereon to produce an organic EL element.

The emission of both the resulting organic EL elements was wholly uniform. When the thickness of the emission layer on the anode electrode was observed under a cross-section TEM, the difference in thickness of the layer between the center and edge of the anode electrode was 10 nm or less, and formation of a uniform emission layer was thus confirmed.

According to the present invention, there is provided a method for manufacturing a full-color organic EL device by forming an uniform emission layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for manufacturing an organic EL display device, comprising:
forming first, second and third anode electrodes on a surface of a substrate;
forming a hole injection transport layer on the substrate on which the first, second and third anode electrodes have been formed;
forming a first emission layer containing a first luminescent material, on the whole surface of the hole injection transport layer;
irradiating the second and third anode electrodes with light, to remove the first emission layer selectively to expose the hole injection transport layer on the second and third anode electrodes;
forming a second emission layer containing a second luminescent material, on the first emission layer and on the exposed hole injection transport layer;
irradiating the third anode electrode with light to remove the second emission layer selectively, to expose the hole injection transport layer on the third anode electrode;
forming a third emission layer containing a third luminescent material, on the second emission layer and on the exposed hole injection transport layer; and
forming a cathode electrode over the first, second and third anode electrodes via at least one of the first, second and third emission layers.

2. The method according to claim 1, wherein the first emission layer is a red emission layer, the second emission layer is a green emission layer, and the third emission layer is a blue emission layer.

3. The method according to claim 1, wherein the emission layers are formed by vapor deposition of the luminescent material.

4. The method according to claim 1, further comprising:
forming an electron injection layer and/or an electron transport layer after formation of the third emission layer and before formation of the cathode electrode.

5. The method according to claim 1, wherein the emission layer is removed by sublimation or evaporation of the luminescent material.

6. The method according to claim 5, wherein the luminescent material is sublimated or evaporated by irradiating the anode electrode with light to generate heat by which the emission layer is heated.

7. The method according to claim 6, wherein the anode electrode is composed of a metal.

8. The method according to claim 7, wherein the metal is molybdenum.

9. The method according to claim 8, wherein the anode electrode is irradiated with light of wavelengths in the range of 380 to 10600 nm.

10. The method according to claim 9, wherein the light is a laser beam.

11. The method according to claim 1, wherein the anode electrode is irradiated with the light applied at the back side of the substrate.

12. The method according to claim 1, wherein the anode electrode is irradiated with the light in a reduced-pressure atmosphere.

13. A method for manufacturing an organic EL display device, comprising:
forming first, second and third anode electrodes and a hole injection transport layer successively on each of two substrates, to prepare a first substrate having a hole injection transport layer and a second substrate having a hole injection transport layer;
forming a first emission layer containing a first luminescent material, on the whole surface of the hole injection transport layer in the first substrate having a hole injection transport layer;
arranging the first emission layer in the first substrate having a hole injection transport layer opposite to the hole injection transport layer in the second substrate having a hole injection transport layer with a gap between the two layers;
irradiating the second and third anode electrodes in the first substrate having a hole injection transport layer with light, to remove the first luminescent material selectively, thereby exposing the hole injection transport layer on the second and third anode electrodes in the first substrate having a hole injection transport layer and simultaneously depositing the removed first luminescent material on the hole injection transport layer on the first and second anode electrodes in the second substrate having a hole injection transport layer, thereby selectively forming a first emission layer on the second substrate.

14. The method according to claim 13, further comprising:
forming a second emission layer containing a second luminescent material, on the first emission layer and on the exposed hole injection transport layer over the first substrate having a hole injection transport layer;
irradiating the third anode electrode with light to remove the second emission layer selectively, to expose the hole injection transport layer on the third anode electrode;
forming a third emission layer containing a third luminescent material, on the second emission layer and on the exposed hole injection transport layer; and
forming a cathode electrode over the first, second and third anode electrodes via at least one of the first, second and third emission layers.

15. The method according to claim 13, further comprising:
irradiating the second and third anode electrodes the second substrate having a hole injection transport layer with light, to remove the first emission layer selectively to expose the hole injection transport layer on the second and third anode electrodes;
forming a second emission layer containing a second luminescent material, on the first emission layer and on the exposed hole injection transport layer;
irradiating the third anode electrode with light to remove the second emission layer selectively, to expose the hole injection transport layer on the third anode electrode;
forming a third emission layer containing a third luminescent material, on the second emission layer and on the exposed hole injection transport layer; and
forming a cathode electrode over the first, second and third anode electrodes via at least one of the first, second and third emission layers.

16. A method for manufacturing an organic EL display device, comprising:
forming a hole injection transport layer on a transparent substrate having first, second and third anode electrodes formed thereon;
forming a first emission layer containing a first luminescent material, on the hole injection transport layer;
irradiating the second and third anode electrodes with light applied at the back side of the transparent substrate, to remove the first emission layer selectively to expose the hole injection transport layer on the second and third anode electrodes;
forming a second emission layer containing a second luminescent material, on the first emission layer and on the exposed hole injection transport layer;
irradiating the third anode electrode with light to remove the second emission layer selectively, to expose the hole injection transport layer on the third anode electrode;
forming a third emission layer containing a third luminescent material, on the second emission layer and on the exposed hole injection transport layer; and
forming a cathode electrode over the first, second and third anode electrodes via at least one of the first, second and third emission layers.

17. The method according to claim 16, wherein the light is a laser beam.

18. The method according to claim 17, wherein a wavelength of the laser beam is in the range of 380 to 10600 nm.

19. The method according to claim 16, wherein the anode electrode is composed of molybdenum.

20. The method according to claim 16, wherein the light irradiation is conducted in a reduced-pressure atmosphere.
